(19) United States
(12) Patent Application Publication
(10) Pub. No.: US 2023/0402348 A1
(43) Pub. Date: Dec. 14, 2023

(54) SEMICONDUCTOR DEVICE AND METHOD FOR MANUFACTURING SEMICONDUCTOR DEVICE

(71) Applicant: ROHM CO., LTD., Kyoto-shi, Kyoto (JP)

(72) Inventor: Yosui FUTAMURA, Kyoto-shi, Kyoto (JP)

(21) Appl. No.: 18/253,501

(22) PCT Filed: Dec. 20, 2021
(86) PCT No.: PCT/JP2021/046945

§ 371 Date: May 18, 2023

(30) Foreign Application Priority Data
Jan. 4, 2021 (JP) 2021-000236

(51) Int. Cl. H01L 23/495; H01L 23/31; H01L 21/48; H01L 21/56

(52) U.S. Cl. CPC H01L 23/49513; H01L 23/3107; H01L 23/4952; H01L 23/49524; H01L 23/49562; H01L 23/49582; H01L 21/4825; H01L 21/4842; H01L 21/565

(57) ABSTRACT

A semiconductor device includes: a support member having an obverse surface facing in a thickness direction; a semiconductor element mounted on the obverse surface; and a bonding layer that bonds the obverse surface and the semiconductor element. The support member has a base member, and a metal layer mounted on the base member and including the obverse surface. The support member includes a first region in contact with the bonding layer, and a second region adjacent to the first region as viewed in the thickness direction. The bonding layer contains a metal composition in a solid phase. The second region is more repellent to a liquid phase of the metal composition than the first region.

### TECHNICAL FIELD

The present disclosure relates to a semiconductor device with a bonding layer bonding a support member and a semiconductor element and containing a metal composition, and relates to a method for manufacturing such a semiconductor device.

### BACKGROUND ART

Patent document 1 discloses an example of a semiconductor device provided with a MOSFET as a semiconductor element. The semiconductor device includes a support member (drain lead) to which source voltage is applied and that supports the MOSFET, a gate lead for inputting an electric signal to the MOSFET, and a source lead through which a current converted by the MOSFET according to the source voltage and the electric signal flows. The MOSFET has a drain electrode electrically connected to the drain lead, a gate electrode electrically connected to the gate lead, and a source electrode electrically connected to the source lead. The drain electrode is bonded to the support member via a bonding layer (solder). A metal clip is bonded to the gate electrode and the gate lead, and another metal clip is bonded to the source electrode and the source lead. This makes it possible to supply a larger current to the semiconductor device.

In recent years, semiconductor devices, each provided with a MOSFET including a compound semiconductor substrate made of silicon carbide (SiC), for example, have become increasingly popular. The MOSFET has advantages over the conventional MOSFETs in that it has a smaller size and provides improved power conversion efficiency. In the case where the MOSFET is used in the semiconductor device disclosed in Patent document 1, the MOSFET may be displaced relative to the support member when the drain electrode is bonded to the support member via the bonding layer. This is because the MOSFET is relatively lightweight and because the bonding layer (solder) is melted by reflow soldering and wetly spreads over the support member. Accordingly, there is a demand for regulating the wetting and spreading of the bonding layer over the support member to prevent the displacement of the MOSFET relative to the support member.

### PRIOR ART DOCUMENT

### Patent Document

Patent Document 1: JP-A-2001-274206

### SUMMARY OF INVENTION

### Problem to be Solved by the Invention

In view of the above circumstances, an object of the present disclosure is to provide a semiconductor device capable of regulating the wetting and spreading of a bonding layer over a support member. Another object of the present disclosure is to provide a method for manufacturing such a semiconductor device.

### Means to Solve the Problem

Provided by a first aspect of the present disclosure, a semiconductor device includes: a support member having an obverse surface facing in a thickness direction; a semiconductor element mounted on the obverse surface; and a bonding layer that bonds the obverse surface and the semiconductor element. The support member has a base member, and a metal layer mounted on the base member and providing the obverse surface. The support member includes a first region in contact with the bonding layer, and a second region adjacent to the first region as viewed in the thickness direction. The bonding layer contains a metal composition in a solid phase. The second region is more repellent to a liquid phase of the metal composition than the first region.

Provided by a second aspect of the present disclosure, a method for manufacturing a semiconductor device includes the steps of: forming a metal layer on a base member having an obverse surface facing in a thickness direction, such that the metal layer covers the obverse surface, arranging a bonding material on a first region of the metal layer, the bonding material containing a metal composition; arranging a semiconductor element on the bonding material; and bonding the semiconductor element to the metal layer by melting and solidifying the bonding material, wherein the method further includes a step of irradiating a second region of the metal layer with a laser between the step of forming the metal layer and the step of arranging the semiconductor element, the second region being adjacent to the first region.

### Advantages of Invention

The semiconductor device and the manufacturing method described above can regulate the wetting and spreading of the bonding layer over the support member.

Other features and advantages of the present disclosure will be more apparent from the detailed description given below with reference to the accompanying drawings.

### BRIEF DESCRIPTION OF THE DRAWINGS

FIG. 1 is a perspective view illustrating a semiconductor device according to a first embodiment of the present disclosure.

FIG. 2 is a plan view illustrating the semiconductor device in FIG. 1.

FIG. 3 is a plan view corresponding to FIG. 2, as seen through a sealing resin.

FIG. 4 is a bottom view illustrating the semiconductor device in FIG. 1.

FIG. 5 is a front view illustrating the semiconductor device in FIG. 1.

FIG. 6 is a cross-sectional view taken along line VI-VI in FIG. 3.

FIG. 7 is a cross-sectional view taken along line VII-VII in FIG. 3.

FIG. 8 is a partially enlarged view of FIG. 3.

FIG. 9 is a partially enlarged view of FIG. 6.

FIG. 10 is a partially enlarged cross-sectional view of the semiconductor device in FIG. 1.

FIG. 11 is a partially enlarged view of FIG. 6.

FIG. 12 is a plan view illustrating a manufacturing step of the semiconductor device in FIG. 1.

FIG. 13 is a plan view illustrating a manufacturing step of the semiconductor device in FIG. 1.

FIG. 14 is a plan view illustrating a manufacturing step of the semiconductor device in FIG. 1.

FIG. 15 is a partially enlarged cross-sectional view illustrating a manufacturing step of the semiconductor device in FIG. 1.

FIG. 16 is a partially enlarged cross-sectional view illustrating a manufacturing step of the semiconductor device in FIG. 1.

FIG. 17 is a plan view illustrating a manufacturing step of the semiconductor device in FIG. 1.

FIG. 18 is a plan view illustrating a manufacturing step of the semiconductor device in FIG. 1.

FIG. 19 is a plan view illustrating a manufacturing step of the semiconductor device in FIG. 1.

FIG. 20 is a partially enlarged cross-sectional view of a first variation of the semiconductor device in FIG. 1.

FIG. 21 is a partially enlarged cross-sectional view of a second variation of the semiconductor device in FIG. 1.

FIG. 22 is a partially enlarged cross-sectional view of a third variation of the semiconductor device in FIG. 1.

FIG. 23 is a plan view illustrating a semiconductor device according to a second embodiment of the present disclosure, as seen through a sealing resin.

FIG. 24 is a cross-sectional view taken along line XXIV-XXIV in FIG. 23.

FIG. 25 is a partially enlarged view of FIG. 24.

### MODE FOR CARRYING OUT THE INVENTION

Embodiments of the present disclosure will be described with reference to the accompanying drawings.

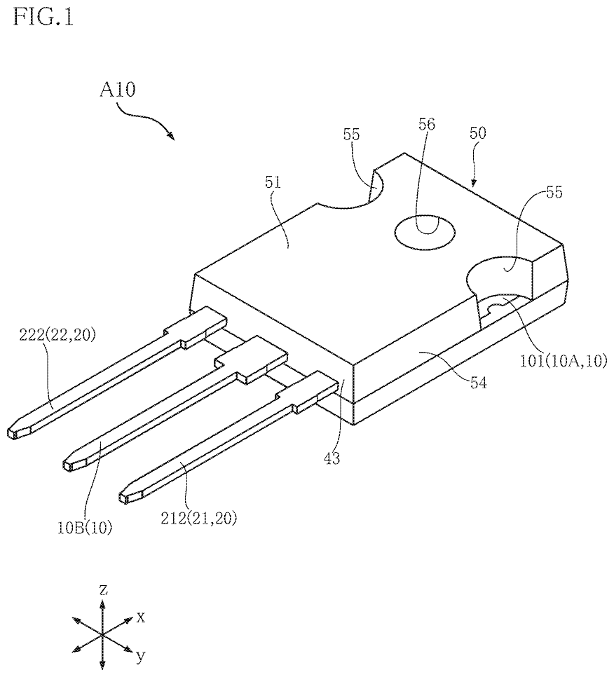

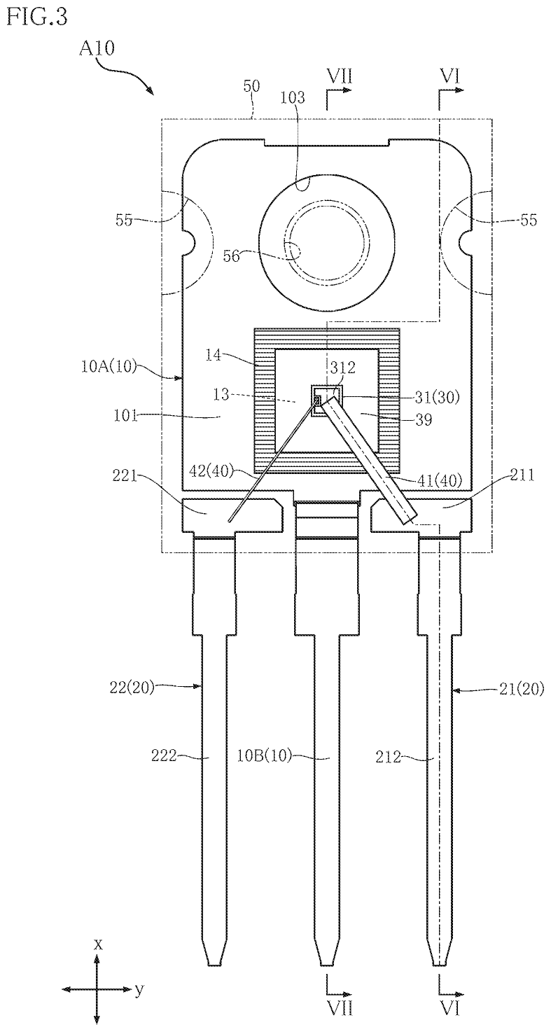

The following describes a semiconductor device A10 according to a first embodiment of the present disclosure, with reference to FIGS. 1 to 11. The semiconductor device A10 may be used in an electronic device including a power conversion circuit, such as a DC-DC converter. The semiconductor device A10 includes a support member 10, a plurality of terminals 20, a semiconductor element 30, a first bonding layer 39, a plurality of conductive members 40, and a sealing resin 50. FIG. 3 shows the sealing resin 50 in phantom for convenience of understanding. In FIG. 3, the sealing resin 50 is indicated by an imaginary line (two-dot chain line).

In the description of the semiconductor device A10, the thickness direction of the support member 10 is referred to as “thickness direction z” for convenience. A direction perpendicular to the thickness direction z is referred to as “first direction x”. The direction perpendicular to both of the thickness direction z and the first direction x is referred to as “second direction y”. In the illustrated example, the first direction x corresponds to the longitudinal direction of the semiconductor device A10 as viewed in the thickness direction z. The second direction y corresponds to the transverse direction of the semiconductor device A10 as viewed in the thickness direction z.

As shown in FIGS. 3, 6, and 7, the semiconductor element 30 is mounted on the support member 10. The support member 10 is electrically conductive. In the semiconductor device A10, the support member 10 includes a die pad section 10A and a terminal section 10B. The die pad section 10A has an obverse surface 101, a reverse surface 102, and a through hole 103. The obverse surface 101 faces in the thickness direction z. The semiconductor element 30 is mounted on the obverse surface 101. The reverse surface 102 faces away from the obverse surface 101 in the thickness direction z. The reverse surface 102 is plated with tin (Sn), for example. The through hole 103 penetrates through the die pad section 10A from the obverse surface 101 to the reverse surface 102 in the thickness direction z. The through hole 103 has a circular shape as viewed in the thickness direction z.

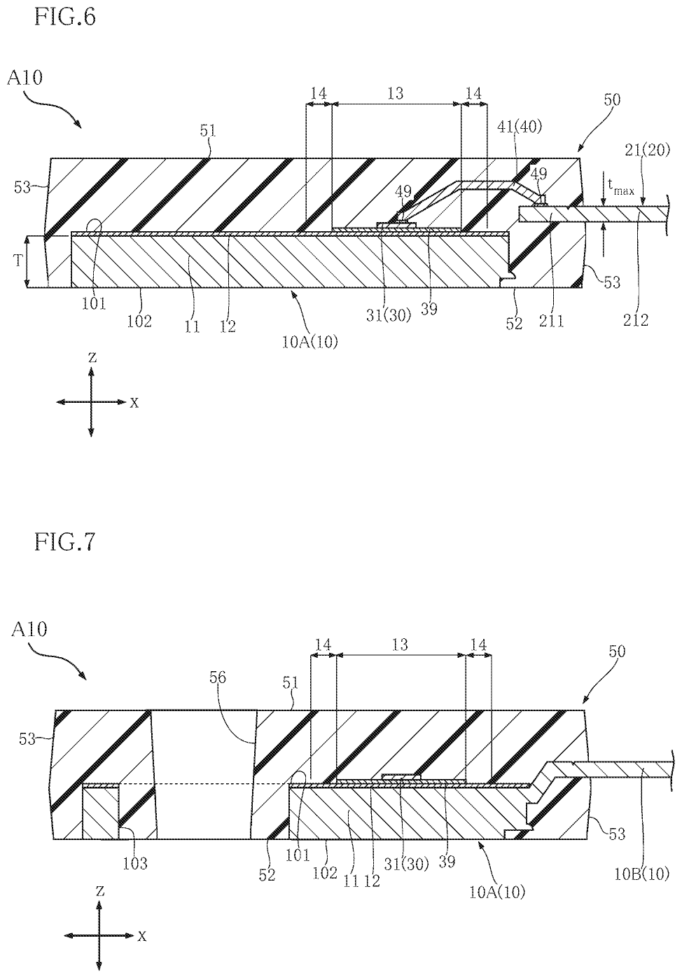

As shown in FIGS. 6 and 7, the die pad section 10A has a base member 11 and a metal layer 12. The base member 11 is the primary element of the die pad section 10A. The base member 11 includes the reverse surface 102. The base member 11, the terminal section 10B, and the terminals 20 are formed from the same lead frame. The lead frame is made of copper (Cu) or a copper alloy. Accordingly, the composition of the base member 11 includes copper, and the composition of the terminals 20 is the same as the composition of the base member 11. As shown in FIG. 6, the thickness T of the base member 11 is larger than the maximum thickness tₘₐₓ of each of the terminals 20.

As shown in FIGS. 6 and 7, the metal layer 12 is formed on the base member 11. The metal layer 12 includes the obverse surface 101. The thickness of the metal layer 12 is smaller than the thickness T of the base member 11. The composition of the metal layer 12 includes silver (Ag). Alternatively, the composition of the metal layer 12 may include Nickel (Ni). In the semiconductor device A10, the metal layer 12 is formed on the entirety of a surface of the base member 11.

As shown in FIGS. 3 and 7, the terminal section 10B includes a portion extending along the first direction x, and is connected to the base member 11 of the die pad section 10A. Thus, the die pad section 10A and the terminal section 10B are electrically connected to each other. A portion of the terminal section 10B is covered with the sealing resin 50. The portion of the terminal section 10B covered with the sealing resin 50 is bent as viewed in the second direction y. A portion of the terminal section 10B is exposed from the sealing resin 50, and the surface of the exposed portion is plated with tin.

As shown in FIGS. 3, 6, and 7, the semiconductor element 30 is mounted on the obverse surface 101 of the die pad section 10A. The semiconductor element 30 includes a first element 31. In the following description of the semiconductor device A10, the first element 31 refers to the semiconductor element 30. In the semiconductor device A10, the first element 31 is an n-channel metal-oxide-semiconductor field-effect transistor (MOSFET) having a vertical structure. The first element 31 includes a compound semiconductor substrate. The main material of the compound semiconductor substrate is silicon carbide (SiC). It is also possible to use silicon (Si) as the main material of the compound semiconductor substrate. In the semiconductor device A10, the area of the first element 31 is no greater than 40% of the area of the obverse surface 101, as viewed in the thickness direction z. The first element 31 is not limited to a MOSFET. The first element 31 may be another switching element such as an insulated gate bipolar transistor (IGBT). Furthermore, the first element 31 may be an integrated circuit such as an LSI. In short, the first element 31 may be any type of element as long as it is mountable on the obverse surface 101 via the first bonding layer 39.

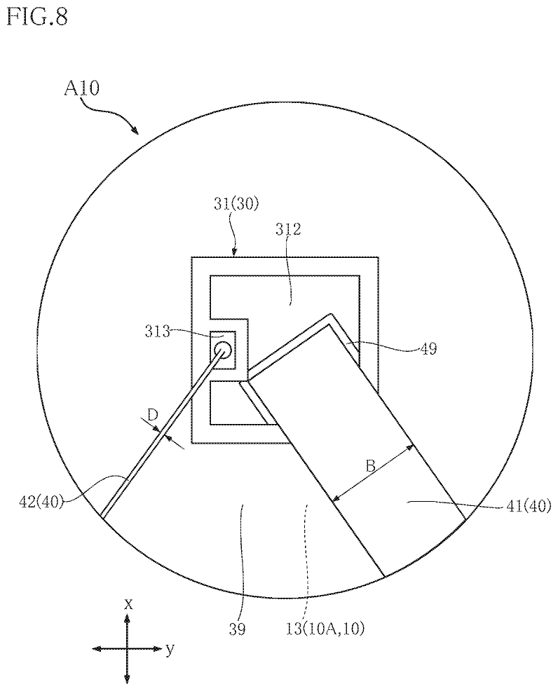

As shown in FIGS. 8 to 10, the first element 31 has a first electrode 311, a second electrode 312, and a third electrode 313. The first electrode 311 faces the obverse surface 101 of the die pad section 10A. The current that flows through the first electrode 311 corresponds to the electric power that has yet to be converted by the first element 31. In other words, the first electrode 311 corresponds to a drain electrode.

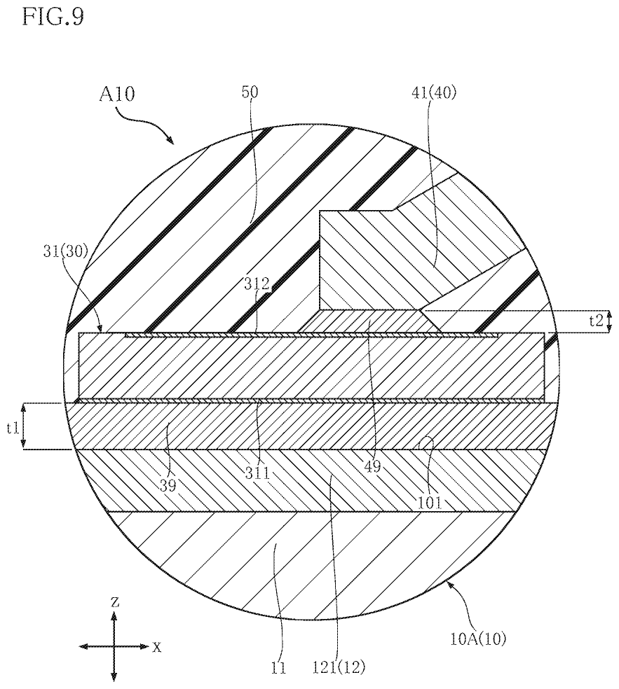

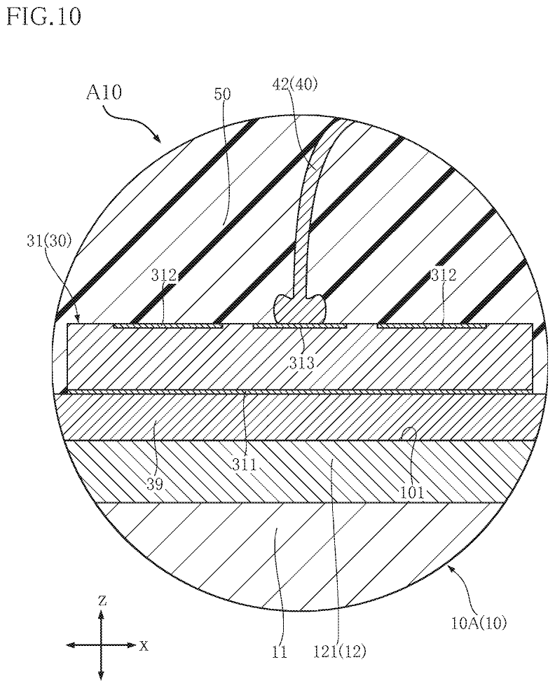

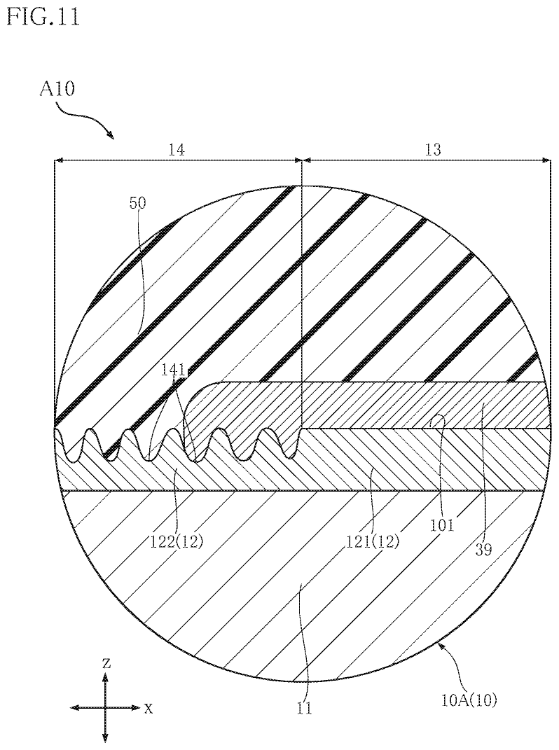

As shown in FIGS. 9 and 10, the second electrode 312 is provided on the opposite side from the first electrode 311 in the thickness direction z. The current that flows through the second electrode 312 corresponds to the electric power that has been converted by the first element 31. In other words, the second electrode 312 corresponds to a source electrode.

As shown in FIGS. 8 and 10, the third electrode 313 is provided on the opposite side from the first electrode 311 in the thickness direction z, and is located away from the second electrode 312. A gate voltage is applied to the third electrode 313 so as to drive the first element 31. In other words, the third electrode 313 corresponds to a gate electrode. As viewed in the thickness direction z, the area of the third electrode 313 is smaller than the area of the second electrode 312.

As shown in FIGS. 6 and 7, the first bonding layer 39 bonds the obverse surface 101 of the die pad section 10A and the first electrode 311 of the first element 31. The first bonding layer 39 is electrically conductive. As a result, the terminal section 10B is electrically connected to the first electrode 311. As such, the terminal section 10B corresponds to a drain terminal of the semiconductor device A10. The first bonding layer 39 contains a metal composition in a solid phase. The metal composition contains tin. In this case, the melting point of the metal composition is approximately 270° C. The first bonding layer 39 is made of solder, for example.

As shown in FIG. 3, the die pad section 10A includes a first region 13 and a second region 14. The first region 13 is in contact with and covered by the first bonding layer 39. As such, the first element 31 is mounted on the obverse surface 101 of the first region 13. The second region 14 is adjacent to the first region 13 as viewed in the thickness direction z. In the semiconductor device A10, the second region 14 surrounds the first region 13 as viewed in the thickness direction z. The second region 14 is more repellent to the liquid phase of the metal composition contained in the first bonding layer 39 than the first region 13.

As shown in FIG. 11, the metal layer 12 has a first portion 121 and a second portion 122. The first portion 121 is included in the first region 13. The second portion 122 is included in the second region 14. The second region 14 is formed with a plurality of grooves 141 which extend in a direction crossing the thickness direction z and are aligned in parallel to each other. In the semiconductor device A10, the grooves 141 are formed only in the second portion 122. Accordingly, in the second region 14, the base member 11 is entirely covered by the second portion 122. On the other hand, in the first region 13, the grooves 141 are not formed, and the obverse surface 101 of the die pad section 10A corresponding to the first portion 121 is flat. Accordingly, the surface roughness of the second region 14 is greater than the surface roughness of the first region 13.

As shown in FIG. 3, the terminals 20 are located away from the support member 10. The terminals 20 are electrically connected to the first element 31. The terminals 20 include a first terminal 21 and a second terminal 22.

As shown in FIG. 3, the first terminal 21 extends along the first direction x, and is located adjacent to the terminal section 10B in the second direction y. The first terminal 21 is electrically connected to the second electrode 312 of the first element 31. As such, the first terminal 21 corresponds to a source terminal of the semiconductor device A10. The first terminal 21 has a covered portion 211 and an exposed portion 212. The covered portion 211 is covered with the sealing resin 50. The exposed portion 212 is connected to the covered portion 211 and exposed from the sealing resin 50. The exposed portion 212 extends from the covered portion 211 to the side away from the die pad section 10A in the first direction x. The surface of the exposed portion 212 is plated with tin, for example.

As shown in FIG. 3, the second terminal 22 extends along the first direction x, and is located on the opposite side from the first terminal 21 with respect to the terminal section 10B in the second direction y. The second terminal 22 is electrically connected to the third electrode 313 of the first element 31. As such, the second terminal 22 corresponds to a gate terminal of the semiconductor device A10. The second terminal 22 has a covered portion 221 and an exposed portion 222. The covered portion 221 is covered with the sealing resin 50. The exposed portion 222 is connected to the covered portion 221 and exposed from the sealing resin 50. The exposed portion 222 extends from the covered portion 221 to the side away from the die pad section 10A in the first direction x. The surface of the exposed portion 222 is plated with tin, for example.

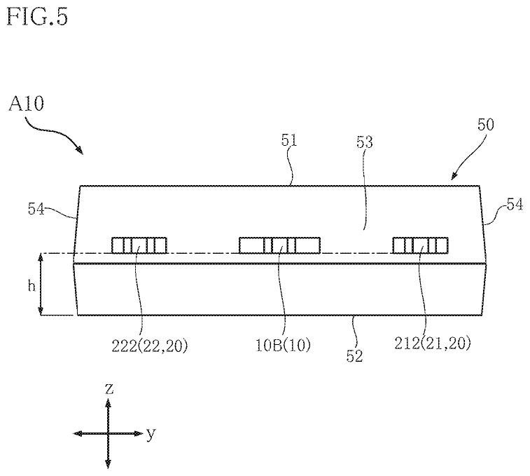

As shown in FIG. 5, in the semiconductor device A10, the portion of the terminal section 10B exposed from the sealing resin 50, the exposed portion 212 of the first terminal 21, and the exposed portion 222 of the second terminal 22 are all equal in height h. As viewed in the second direction y, at least a portion of the terminal section 10B overlaps with each of the first terminal 21 and the second terminal 22.

As shown in FIG. 3, the conductive members 40 are bonded to the first element 31 and the terminals 20. As a result, the first element 31 and the terminals 20 are electrically connected to each other. In the semiconductor device A10, the conductive members 40 include a first member 41 and a second member 42.

As shown in FIGS. 3, 6, and 9, the first member 41 is bonded to the second electrode 312 of the first element 31 and the covered portion 211 of the first terminal 21. As a result, the first terminal 21 is electrically connected to the second electrode 312. The composition of the first member 41 includes copper. In the semiconductor device A10, the first member 41 is a metal clip having a standard length. The first member 41 is bonded to the second electrode 312 and the covered portion 211 via a second bonding layer 49. The second bonding layer 49 is electrically conductive. The composition of the second bonding layer 49 includes tin. The second bonding layer 49 has a lower melting point than the first bonding layer 39. The second bonding layer 49 is solder, for example. As shown in FIG. 9, the thickness t2 of the second bonding layer 49 is smaller than the thickness t1 of the first bonding layer 39. Alternatively, the first member 41 may be a wire. In this case, the second bonding layer 49 is no longer needed, since the first member 41 is formed by wire bonding.

As shown in FIGS. 3 and 10, the second member 42 is bonded to the third electrode 313 of the first element 31 and the covered portion 221 of the second terminal 22. As a result, the second terminal 22 is electrically connected to the third electrode 313. The composition of the second member 42 includes aluminum (Al). In the semiconductor device A10, the second member 42 is a wire. The second member 42 is formed by wire bonding.

The following describes the difference between the first member 41 and the second member 42. The second member 42 has a smaller Young's modulus (modulus of elasticity) than the first member 41. This is based on the fact that the composition of the first member 41 includes copper and the composition of the second member 42 includes aluminum, as described above. As a result, the second member 42 has a coefficient of linear expansion larger than the first member 41. In addition, the second member 42 has a smaller thermal conductivity than the first member 41. Furthermore, as shown in FIG. 8, the width B of the first member 41 is larger than the width (diameter) D of the second member 42.

As shown in FIGS. 6 and 7, the sealing resin 50 covers the first element 31, the conductive members 40, a portion of the support member 10, and portions of the terminals 20. The sealing resin 50 is electrically insulative. The sealing resin 50 is made of a material containing black epoxy resin, for example. The sealing resin 50 has a top surface 51, a bottom surface 52, a pair of first side surfaces 53, a pair of second side surfaces 54, a pair of openings 55, and a mounting hole 56.

As shown in FIGS. 6 and 7, the top surface 51 faces the same side as the obverse surface 101 of the die pad section 10A in the thickness direction z. As shown in FIGS. 5 and 7, the bottom surface 52 faces away from the top surface 51 in the thickness direction z. The reverse surface 102 of the die pad section 10A is exposed from the bottom surface 52.

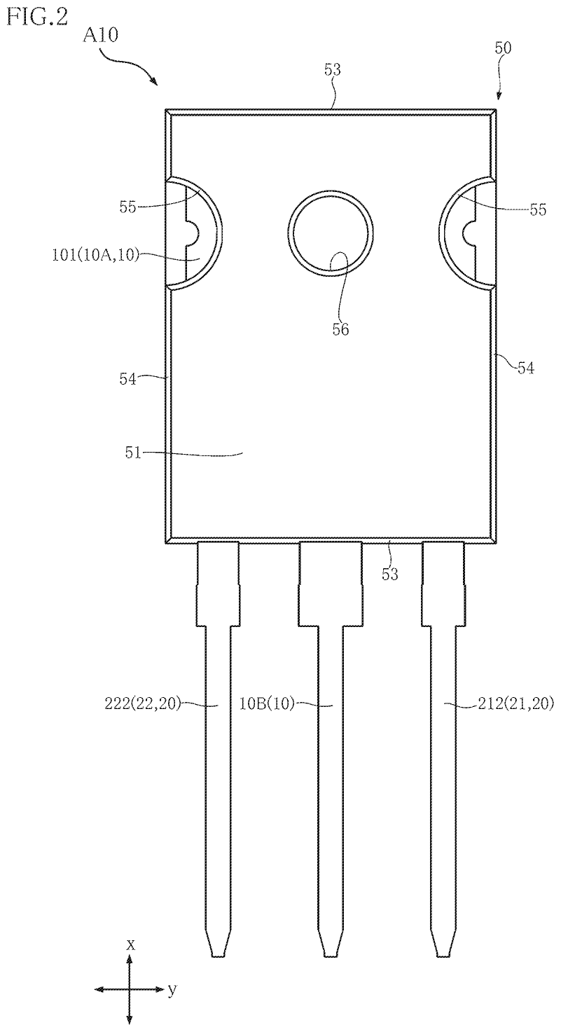

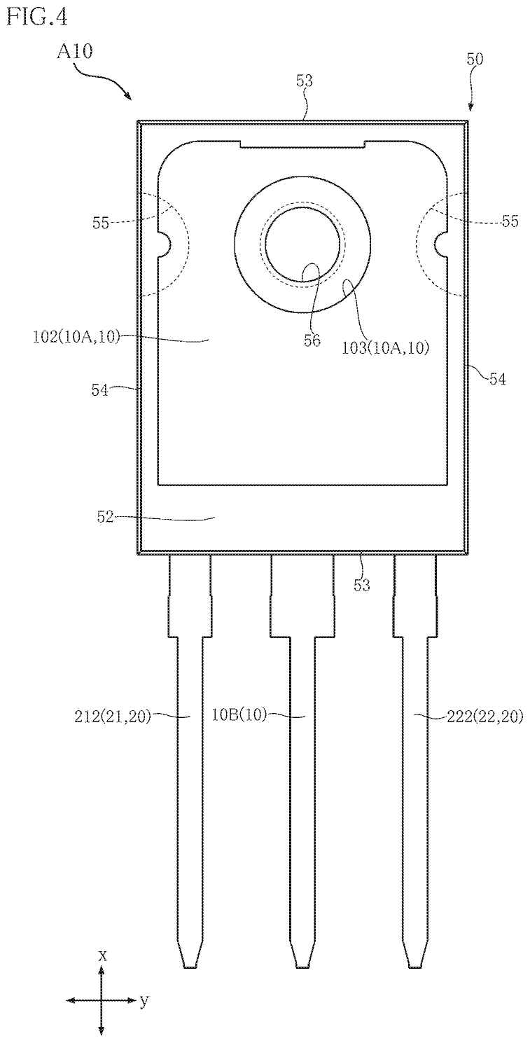

As shown in FIGS. 2 and 4, the pair of first side surfaces 53 are spaced apart from each other in the first direction x. The pair of first side surfaces 53 are connected to the top surface 51 and the bottom surface 52. As shown in FIG. 5, a portion of the terminal section 10B, the exposed portion 212 of the first terminal 21, and the exposed portion 222 of the second terminal 22 are exposed from one of the pair of first side surfaces 53.

As shown in FIGS. 2, 4, and 5, the pair of second side surfaces 54 are spaced apart from each other in the second direction y. The pair of second side surfaces 54 are connected to the top surface 52 and the bottom surface 52. As shown in FIG. 2, the pair of openings 55 are spaced apart from each other in the second direction y. Each of the openings 55 is recessed from the top surface 51 and one of the pair of second side surfaces 54 toward the inner side of the sealing resin 50. The obverse surface 101 of the die pad section 10A is exposed from the pair of openings 55. As shown in FIGS. 2, 4, and 7, the mounting hole 56 penetrates through the sealing resin 50 from the top surface 51 to the bottom surface 52 in the thickness direction z. As viewed in the thickness direction z, the mounting hole 56 is encompassed by the through hole 103 of the die pad section 10A. The inner circumferential surface of the die pad section 10A that defines the through hole 103 is covered with the sealing resin 50. As a result, the maximum dimension of the mounting hole 56 is smaller than the dimension of the through hole 103, as viewed in the thickness direction z.

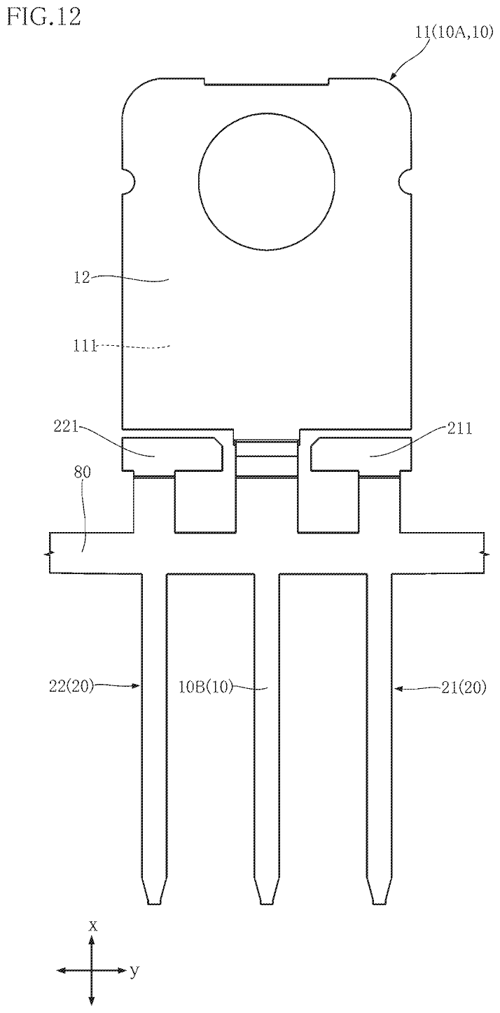

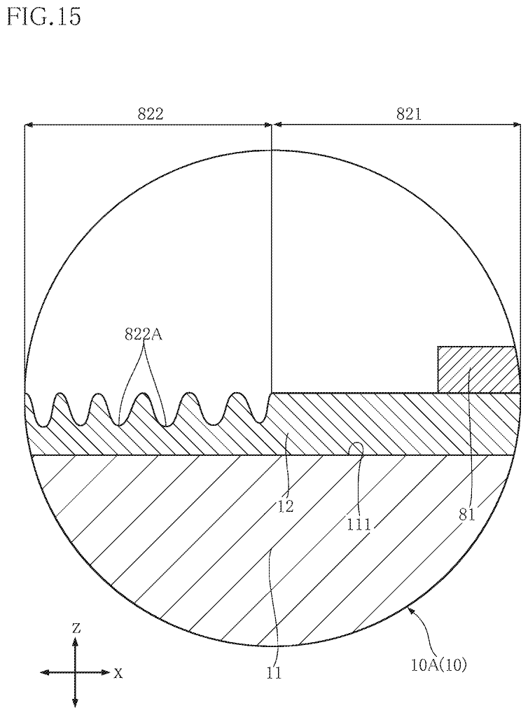

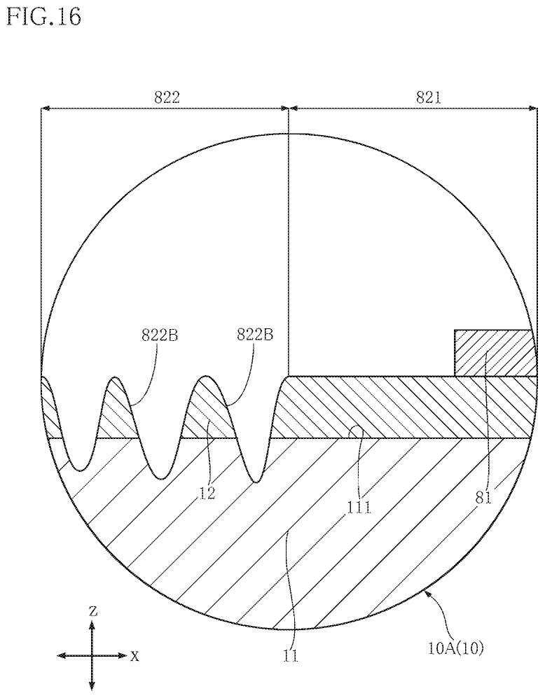

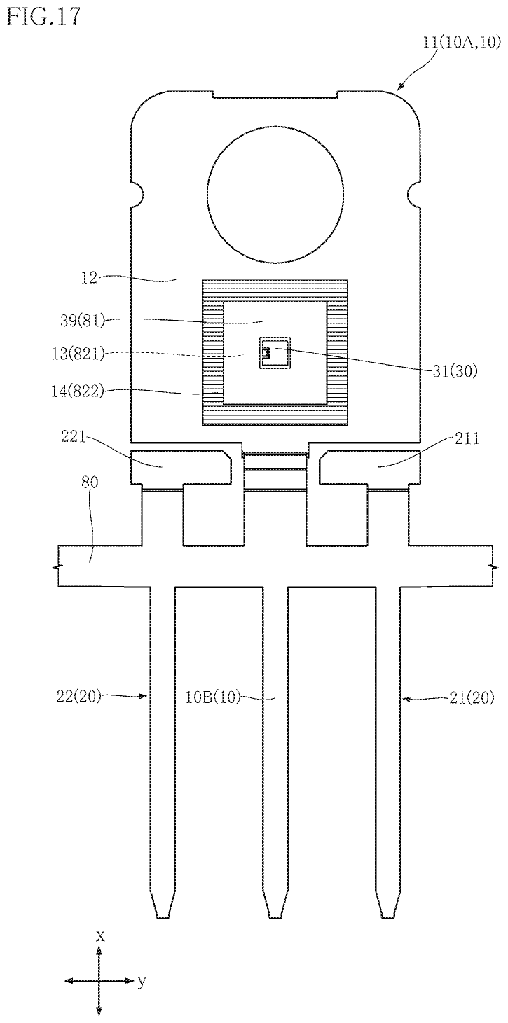

Next, an example of a method for manufacturing the semiconductor device A10 will be described with reference to FIGS. 12 to 19. Note that the cross-sectional positions in FIGS. 15 and 16 are the same as the cross-sectional position in FIG. 11.

First, as shown in FIG. 12, the metal layer 12 is formed to cover a surface 111 of the base member 11 of the support member 10 (die pad section 10A). The support member 10, as well as the terminals 20, is connected to a tie bar 80 extending in the second direction y. The surface 111 faces the same side as the obverse surface 101 of the support member 10 in the thickness direction z. The metal layer 12 is formed by electrolytic plating with the base member 11 used as a conductive path, or is formed by spray-plating.

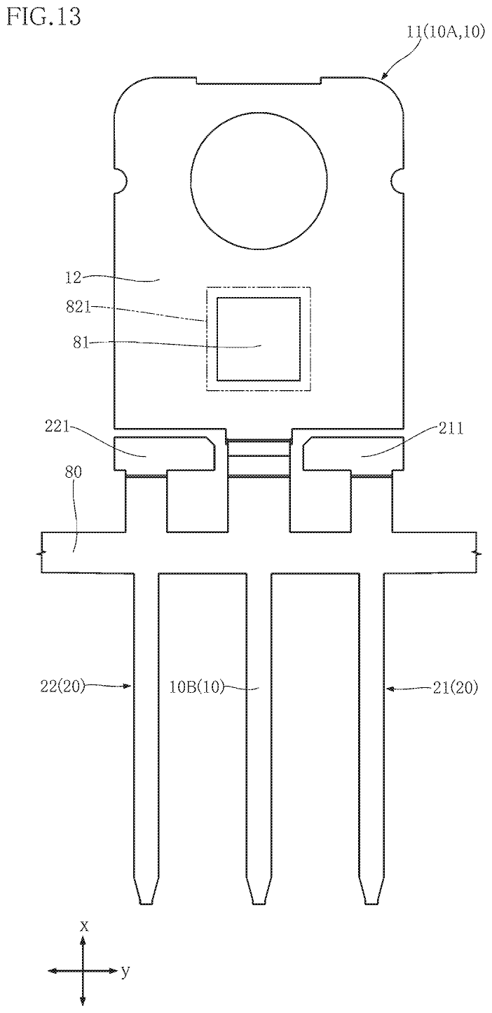

Next, as shown in FIG. 13, a bonding material 81 containing a metal composition is arranged on a first region 821 of the metal layer 12. The metal composition contains tin. The bonding material 81 is cream solder. In this step, cream solder is applied to the first region 821. Alternatively, the bonding material 81 may be wire solder.

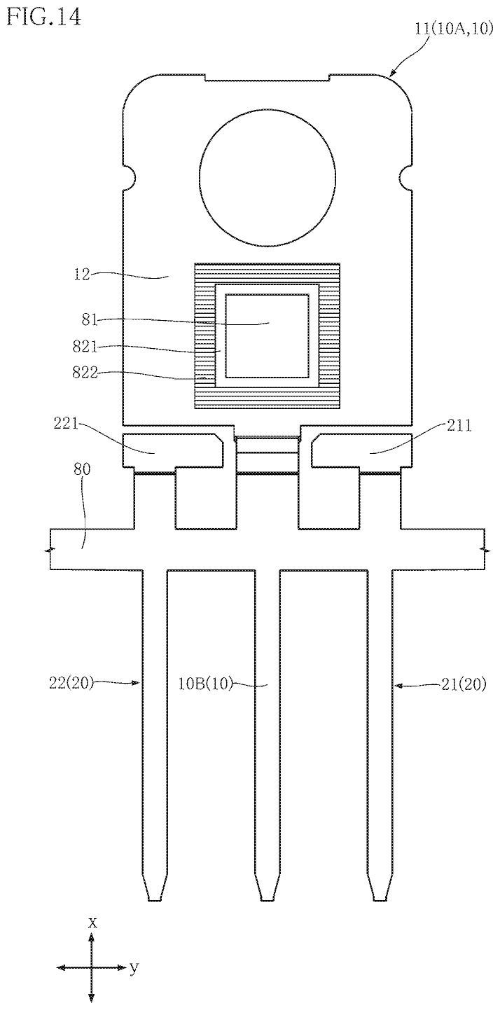

Next, as shown in FIG. 14, a second region 822 of the metal layer 12 is irradiated with a laser. The second region 822 is adjacent to the first region 821 of the metal layer 12. In this manufacturing method, the second region 822 has a frame shape surrounding the first region 821 and the bonding material 81 as viewed in the thickness direction z. Note that this step may be performed between the step of forming the metal layer 12 as shown in FIG. 12 and the step of arranging the bonding material 81 on the first region 821 as shown in FIG. 13. Accordingly, this step is performed between the step of forming the metal layer 12 as shown in FIG. 12 and the step of bonding the semiconductor element 30 as shown in FIG. 17.

FIGS. 15 and 16 each show a partially enlarged cross-sectional view illustrating the metal layer 12 after laser irradiation. As shown in FIG. 15, the second region 822 of the metal layer 12 is formed with a plurality of grooves 822A extending in a direction crossing the thickness direction z. The grooves 822A are aligned in parallel to each other. When the laser output is further increased, the metal layer 12 is brought into a state as shown in FIG. 16. The second region 822 shown in FIG. 16 is formed with a plurality of slits 822B extending in a direction crossing the thickness direction z. The base member 11 is exposed from the slits 822B.

Next, as shown in FIG. 17, after the semiconductor element 30 (first element 31) is disposed on the bonding material 81, the semiconductor element 30 is bonded to the metal layer 12 by melting and solidifying the bonding material 81 by reflow soldering. With this step, the bonding material 81 becomes the first bonding layer 39. The first region 821 of the metal layer 12 becomes the first region 13 of the support member 10. The second region 822 of the metal layer 12 becomes the second region 14 of the support member 10.

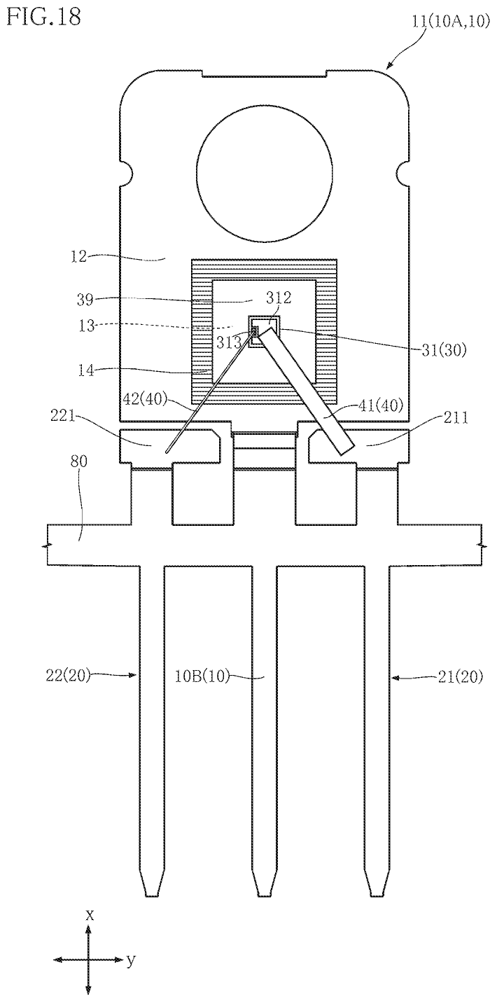

Next, as shown in FIG. 18, the first member 41 of the conductive members 40 is bonded to the second electrode 312 of the semiconductor element 30, and to the covered portion 211 of the first terminal 21. The bonding of the first member 41 is performed by clip bonding. Then, the second member 42 of the conductive members 40 is bonded to the third electrode 313 of the semiconductor element 30 and the covered portion 221 of the second terminal 22. The bonding of the second member 42 is performed by wire bonding.

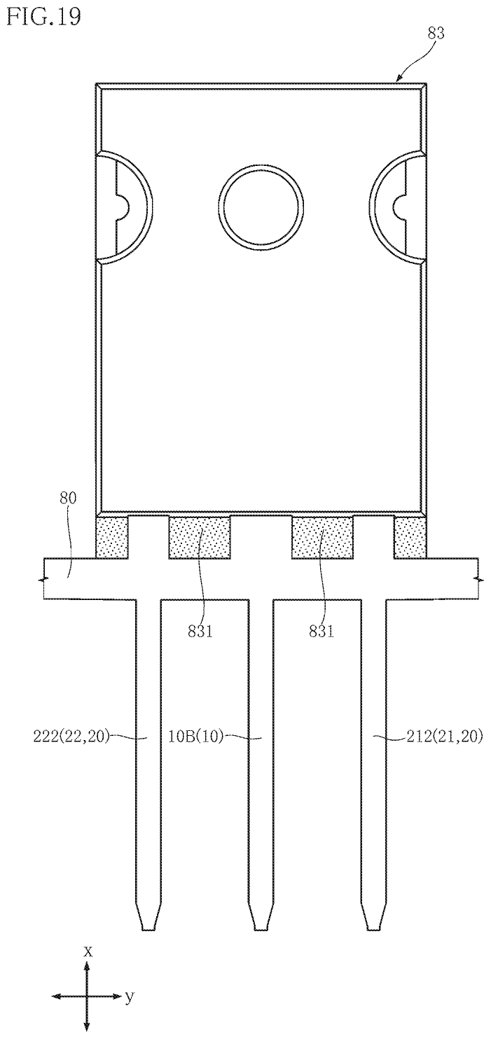

Next, as shown in FIG. 19, a sealing resin 83 is formed to cover the semiconductor element 30, the first member 41 and the second member 42 of the conductive members 40, the support member 10, and portions of the terminals 20. The sealing resin 83 is formed by transfer molding. As a result of forming the sealing resin 83, resin burrs 831 are formed. The resin burrs 831 are dammed by the exposed portion 212 of the first terminal 21, the exposed portion 222 of the second terminal 22, the terminal section 10B of the support member 10, and the tie bar 80. Subsequently, the resin burrs 831 are removed with, for example, high-pressure water. Then, the surfaces of the exposed portion 212 of the first terminal 21, the exposed portion 222 of the second terminal 22, the terminal section 10B, and the reverse surface 102 of the die pad section 10A are plated with tin by electrolytic plating with the tie bar 80 as a conductive path. Finally, the tie bar 80 is cut off to obtain the semiconductor device A10.

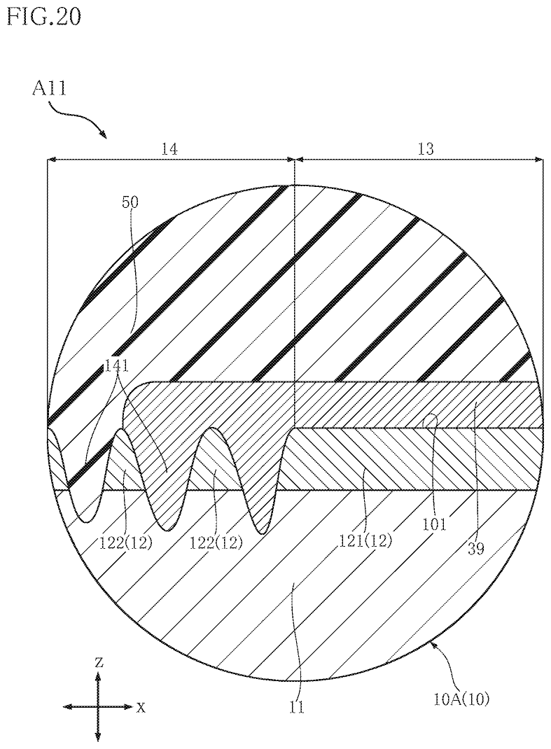

The following describes a semiconductor device A11, which is a first variation of the semiconductor device A10, according to FIG. 20. Note that the cross-sectional position in FIG. 20 is the same as the cross-sectional position in FIG. 11.

As shown in FIG. 20, the semiconductor device A11 is different from the semiconductor device A10 in the configuration of the second region 14 of the die pad section 10A. In the semiconductor device A11, the grooves 141 of the second region 14 are formed in the base member 11. The second portion 122 of the metal layer 12 is formed with a plurality of slits passing through in the thickness direction z and connected to the grooves 141. The base member 11 is exposed from the slits formed in the second portion 122. Such a configuration of the second region 14 is obtained by adjusting a laser output such that the second region 822 is brought into a state as shown in FIG. 16. This adjustment is performed in the step of irradiating the second region 822 of the metal layer 12 with a laser during the manufacturing process of the semiconductor device A10.

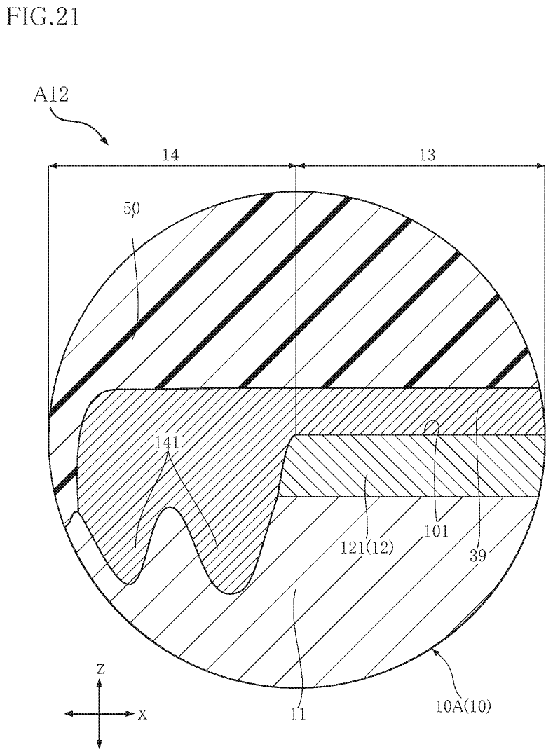

The following describes a semiconductor device A12, which is a second variation of the semiconductor device A10, according to FIG. 21. Note that the cross-sectional position in FIG. 21 is the same as the cross-sectional position in FIG. 11.

As shown in FIG. 21, the semiconductor device A12 is different from the semiconductor device A10 in the configuration of the second region 14 of the die pad section 10A. In the semiconductor device A12, the grooves 141 of the second region 14 are formed in the base member 11. Furthermore, the semiconductor device A12 is configured such that the second portion 122 of the metal layer 12 does not exist in the second region 14.

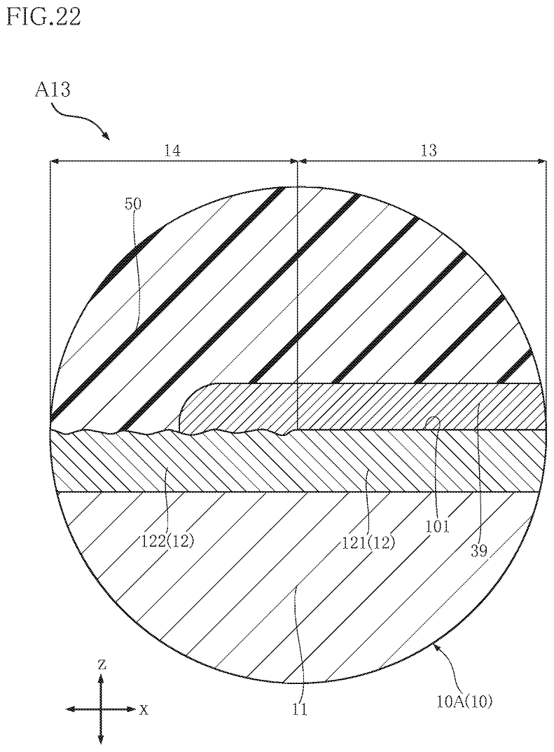

The following describes a semiconductor device A13, which is a third variation of the semiconductor device A10, according to FIG. 22. Note that the cross-sectional position in FIG. 22 is the same as the cross-sectional position in FIG. 11.

As shown in FIG. 22, the semiconductor device A13 is different from the semiconductor device A10 in the configuration of the second region 14 of the die pad section 10A. In the second region 14 of the semiconductor device A13, the obverse surface 101 of the second portion 122 of the metal layer 12 is uneven, but distinct second regions 14 are not formed in the second portion 122. Even in the semiconductor device A13, the surface roughness of the second region 14 is greater than the surface roughness of the first region 13.

The configurations of the variations of the semiconductor device A10, which are shown in FIGS. 20 to 22, are obtained by changing the output of the laser in the step of irradiating the second region 822 of the metal layer 12 with the laser as shown in FIG. 14, in the manufacturing process of the semiconductor device A10. For example, the configuration of the semiconductor device A12 is obtained by setting the output of the laser relatively high. The configuration of the semiconductor device A13 is obtained by setting the output of the laser relatively low.

Next, advantages of the semiconductor device A10 will be described.

The semiconductor device A10 includes the support member 10 (die pad section 10A) having the base member 11 and the metal layer 12 formed on the base member 11. The support member 10 includes the first region 13 in contact with the bonding layer (the first bonding layer 39), and the second region 14 adjacent to the first region 13 as viewed in the thickness direction z. The first bonding layer 39 contains a metal composition in a solid phase. The second region 14 is more repellent to the liquid phase of the metal composition than the first region 13. In other words, the second region 14 is less wettable than the first region 13 with respect to the liquid phase of the metal composition. As such, in the step of bonding the semiconductor element 30 to the metal layer 12 as shown in FIG. 17 in the manufacturing process of the semiconductor device A10, the second region 14 regulates the wetting and spreading of the bonding material 81 in a liquid phase. Hence, the semiconductor device A10 is capable of regulating the wetting and spreading of the first bonding layer 39 over the support member 10. Regulating the wetting and spreading of the first bonding layer 39 can prevent the displacement of the semiconductor element 30 on the bonding material 81 in a liquid phase, during the manufacturing process of the semiconductor device A10 as shown in FIG. 17.

In the semiconductor device A10, the second region 14 is formed with the grooves 141 extending in a direction crossing or perpendicular to the thickness direction z and aligned in parallel to each other. The grooves 141 are formed in the second portion 122 of the metal layer 12 of the support member 10. The second region 14 may be configured such that, as can be seen in the semiconductor device A11, the grooves 141 are formed in the base member 11 of the support member 10 and that the support member 10 is exposed from the second portion 122. Alternatively, the second region 14 may be configured such that, as can be seen in the semiconductor device A12, the grooves 141 are formed in the base member 11, and that the second portion 122 is not provided. Furthermore, the second region 14 may be configured such that, as can be seen in the semiconductor device A13, the grooves 141 formed in the metal layer 12 may not be distinct from each other. The configurations of the second region 14 as described above can be obtained by irradiating the second region 822 of the metal layer 12 with a laser in the step shown in FIG. 14 during the manufacturing process of the semiconductor device A10. As a result, the surface roughness of the second region 14 is greater than the surface roughness of the first region 13. The difference in surface roughness may be one factor of the difference in repellency with respect to the liquid phase of the metal composition contained in the first bonding layer 39.

According to the configuration of semiconductor device A10, it is not necessary to accurately form the metal layer 12 only within the range of the first region 13 by using a mask in order to prevent the wetting and spreading of the first bonding layer 39 over the support member 10. This makes it possible to improve the manufacturing efficiency of the semiconductor device A10 while regulating the wetting and spreading of the first bonding layer 39 over the support member 10.

As viewed in the thickness direction z, the second region 14 surrounds the first region 13. In this way, the wetting and spreading of the first bonding layer 39 over the support member 10 can be more reliably regulated.

The semiconductor device A10 further includes the terminals 20 located away from the support member 10 and electrically connected to the semiconductor element 30. As viewed in the thickness direction z, at least a portion of the second region 14 is positioned between the semiconductor element 30 and the terminals 20. This makes it possible to prevent the first bonding layer 39 from acting as a bridge between the support member 10 and the terminals 20. As a result, a short circuit between the support member 10 and the terminals 20 is prevented.

The semiconductor device A10 further includes the sealing resin 50 covering the semiconductor element 30 and portions of the support member 10 and the terminals 20. The sealing resin 50 is in contact with the second region 14. This makes it possible to increase the adhesion strength of the sealing resin 50 to the support member 10.

The thickness t1 of the first bonding layer 39 is larger than the thickness t2 of the second bonding layer 49. In this way, the heat generated from the semiconductor element 30 during the use of the semiconductor device A10 is more likely to be transferred to the die pad section 10A, which is a relatively large member, rather than to the conductive members 40, which are relatively small members. This makes it possible to improve the heat dissipation of the semiconductor device A10.

The composition of the base member 11 of the support member 10 includes copper. Furthermore, the thickness T of the base member 11 of the die pad section 10A is larger than the maximum thickness tₘₐₓ of each of the terminals 20. This makes it possible to improve the heat conductivity of the die pad section 10A while enhancing the efficiency of heat conduction in a direction perpendicular to the thickness direction z. This contributes to improvement of the heat dissipation of the die pad section 10A.

The die pad section 10A has the reverse surface 102 facing away from the obverse surface 101 in the thickness direction z. The reverse surface 102 is exposed from the sealing resin 50. This makes it possible to protect the semiconductor element 30 and the conductive members 40 from external factors with the use of the sealing resin 50 while avoiding the deterioration of the heat dissipation of the semiconductor device A10.

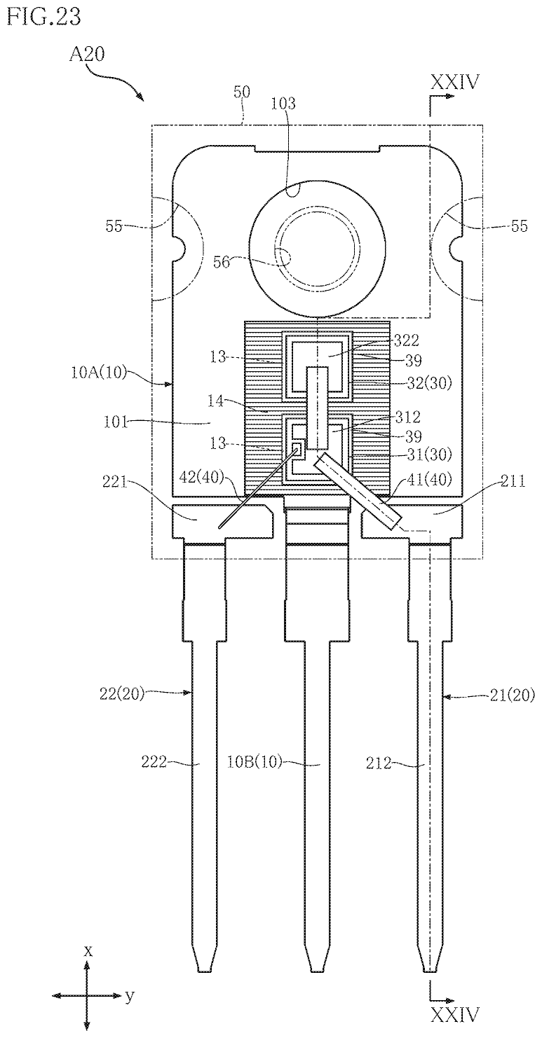

The following describes a semiconductor device A20 according to a second embodiment of the present disclosure, with reference to FIGS. 23 to 25. In these figures, elements that are the same as or similar to those of the semiconductor device A10 are denoted by the same reference signs and descriptions thereof are omitted. FIG. 23 shows the sealing resin 50 in phantom for convenience of understanding. In FIG. 23, the sealing resin 50 is indicated by an imaginary line.

The semiconductor device A20 is different from the semiconductor device A10 in the configurations of the semiconductor element 30 and the conductive members 40. The conductive members 40 further include a third member 43, in addition to the first member 41 and the second member 42.

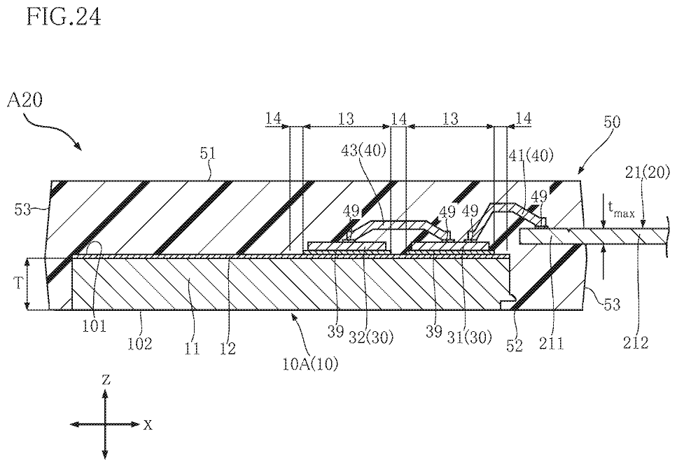

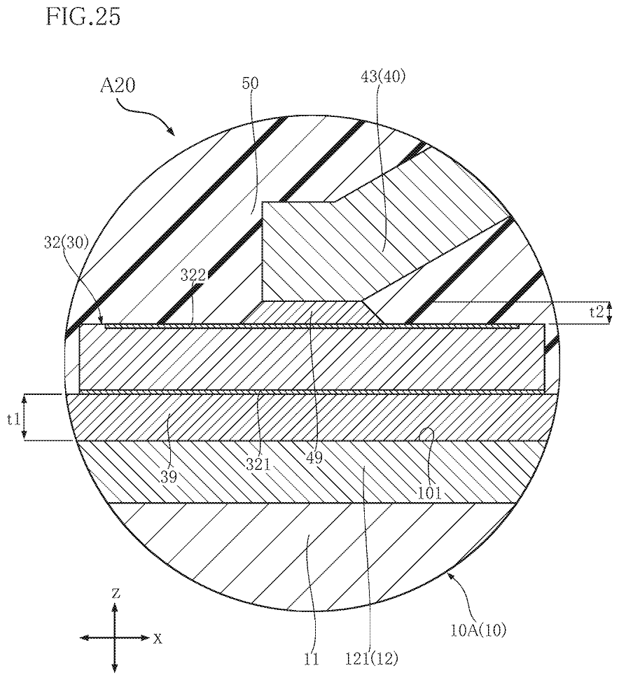

As shown in FIGS. 23 and 24, the semiconductor element 30 includes a second element 32, in addition to the first element 31. In the semiconductor device A20, the first element 31 is an IGBT. The first element 31 has the first electrode 311, the second electrode 312, and the third electrode 313, which are shown in FIGS. 9 and 10. The first electrode 311 corresponds to a collector electrode. The second electrode 312 corresponds to an emitter electrode. The third electrode 313 corresponds to a gate electrode.

As shown in FIGS. 23 and 24, the second element 32 and the first element 31 are spaced apart from each other. The second element 32 is a Schottky barrier diode, for example. The second element 32 is connected in parallel to the first element 31. The second element 32 is a so-called freewheeling diode that allows current to flow through the second element 32 instead of the first element 31 when reverse bias is applied to the first element 31. This makes it possible to protect the first element 31 from reverse bias. The type of the second element 32 is not limited to a diode. The second element 32 may be of any type as long as it is mountable on the obverse surface 101 of the die pad section 10A via the first bonding layer 39 in the same manner as the first element 31.

As shown in FIG. 25, the second element 32 has a first electrode 321 and a second electrode 322. The first electrode 321 is provided to face the obverse surface 101 of the die pad section 10A. The first electrode 321 corresponds to a cathode electrode of the second element 32. The first electrode 321 is bonded to the obverse surface 101 via the first bonding layer 39. Accordingly, the die pad section 10A has a portion in contact with the first bonding layer 39 that bonds the obverse surface 101 and the first electrode 321, and this portion of the die pad section 10A also corresponds to the first region 13 of the support member 10. The first electrode 321 is electrically connected to the first electrode 311 of the first element 31 via the first bonding layer 39 and the support member 10. The second electrode 322 is provided on the opposite side from the first electrode 321 in the thickness direction z. The second electrode 322 corresponds to an anode electrode of the second element 32.

As shown in FIGS. 24 and 25, the third member 43 of the conductive members 40 is bonded to the second electrode 312 of the first element 31 and the second electrode 322 of the second element 32 via the second bonding layer 49. The composition of the third member 43 includes copper. As with the first member 41, the third member 43 of the semiconductor device A20 is a metal clip having a standard length. As a result, the second electrode 322 of the second element 32 and the second electrode 312 of the first element 31 are electrically connected to each other.

As shown in FIG. 23, at least a portion of the second region 14 of the support member 10 is located between the first element 31 and the second element 32. As viewed in the thickness direction z, the second region 14 surrounds the first region 13 of the support member 10 in which the first element 31 is disposed via the first bonding layer 39, and also surrounds the first region 13 of the support member 10 in which the second element 32 is disposed via the first bonding layer 39.

Next, advantages of the semiconductor device A20 will be described.

The semiconductor device A20 includes the support member 10 (die pad section 10A) having the base member 11 and the metal layer 12 formed on the base member 11. The support member 10 includes the first regions 13 in contact with the bonding layers (the first bonding layers 39), and the second region 14 adjacent to the first regions 13 as viewed in the thickness direction z. The first bonding layers 39 each contain a metal composition in a solid phase. The second region 14 is more repellent to the liquid phase of the metal composition than the first regions 13. Hence, the semiconductor device A20 is also capable of regulating the wetting and spreading of the first bonding layers 39 over the support member 10.

In the semiconductor device A20, the semiconductor element 30 includes the first element 31 and the second element 32 that are spaced apart from each other. As viewed in the thickness direction z, at least a portion of the second region 14 of the support member 10 is positioned between the first element 31 and the second element 32. This makes it possible to regulate the first bonding layer 39 that bonds the obverse surface 101 of the support member 10 and the first element 31, and also to regulate the first bonding layer 39 that bonds the obverse surface 101 and the second element 32, such that these first bonding layers 39 do not wetly spread over the support member 10.

The semiconductor element 30 according to any of the foregoing embodiments is mainly intended for use in power conversion. The present disclosure is not limited to the semiconductor element 30 for such use, and is applicable to other semiconductor elements 30 for various applications as long as they are bonded to the support member 10 via first bonding layers 39.

The present disclosure is not limited to the foregoing embodiments. Various design changes can be made to the specific configurations of the elements of the present disclosure.

The present disclosure includes embodiments described in the following clauses.

Clause 1.

A semiconductor device comprising:
a support member having an obverse surface facing in a thickness direction;
a semiconductor element mounted on the obverse surface; and
a bonding layer that bonds the obverse surface and the semiconductor element,
wherein the support member includes a base member, and a metal layer mounted on the base member and providing the obverse surface,
the support member includes a first region in contact with the bonding layer, and a second region adjacent to the first region as viewed in the thickness direction,
the bonding layer contains a metal composition in a solid phase, and
the second region is more repellent to a liquid phase of the metal composition than the first region.

Clause 2.

The semiconductor device according to clause 1, wherein a surface roughness of the second region is greater than a surface roughness of the first region.

Clause 3.

The semiconductor device according to clause 2, wherein the second region is formed with a plurality of grooves extending in a direction crossing the thickness direction and aligned in parallel to each other.

Clause 4.

The semiconductor device according to clause 3, wherein the metal layer has a first portion included in the first region, and a second portion included in the second region.

Clause 5.

The semiconductor device according to clause 4, wherein the base member is exposed from the second portion.

Clause 6.

The semiconductor device according to any of clauses 1 to 5, wherein the second region surrounds the first region as viewed in the thickness direction.

Clause 7.

The semiconductor device according to any of clauses 1 to 6,
wherein the semiconductor element includes a first element and a second element that are spaced apart from each other, and
at least a portion of the second region is positioned between the first element and the second element, as viewed in the thickness direction.

Clause 8.

The semiconductor device according to any of clauses 1 to 7, wherein a composition of the base member includes copper.

Clause 9.

The semiconductor device according to any of clauses 1 to 8, wherein a composition of the metal layer includes silver.

Clause 10.

The semiconductor device according to any of clauses 1 to 9, wherein the metal composition contains tin.

Clause 11.

The semiconductor device according to any of clauses 1 to 10, further comprising a terminal located away from the support member and electrically connected to the semiconductor element,
wherein at least a portion of the second region is positioned between the semiconductor element and the terminal, as viewed in the thickness direction.

Clause 12.

The semiconductor device according to clause 11, wherein a composition of the terminal is the same as a composition of the base member.

Clause 13.

The semiconductor device according to clause 11 or 12, further comprising a sealing resin covering the semiconductor element and a portion of each of the support member and the terminal,
wherein the sealing resin is in contact with the second region.

Clause 14.

The semiconductor device according to clause 13, further comprising a conductive member bonded to the semiconductor element and the terminal,
wherein the conductive member is covered with the sealing resin.

Clause 15.

The semiconductor device according to clause 13 or 14, wherein the support member has a reverse surface facing away from the obverse surface in the thickness direction, and
the reverse surface is exposed from the sealing resin.

Clause 16.

A method for manufacturing a semiconductor device, comprising the steps of:
forming a metal layer on a base member having an obverse surface facing in a thickness direction, such that the metal layer covers the obverse surface,
arranging a bonding material on a first region of the metal layer, the bonding material containing a metal composition;
arranging a semiconductor element on the bonding material; and
bonding the semiconductor element to the metal layer by melting and solidifying the bonding material,
wherein the method further comprises a step of irradiating a second region of the metal layer with a laser between the step of forming the metal layer and the step of arranging the semiconductor element, the second region being adjacent to the first region.

Clause 17.

The method according to clause 16, wherein a plurality of grooves are formed in the second region in the step of irradiating the second region with a laser, the plurality of grooves extending in a direction crossing the thickness direction and being aligned in parallel to each other.

Clause 18.

The method according to clause 16, wherein a plurality of slits are formed in the second region in the step of irradiating the second region with a laser, the plurality of slits extending in a direction crossing the thickness direction and being aligned in parallel to each other.

### REFERENCE SIGNS

| | |
|---|---|
| A10, A20: Semiconductor device | 10: Support member |
| 101: Obverse surface | 102: Reverse surface |
| 103: Through hole | 10A: Die pad section |
| 10B: Terminal section | 11: Base member |
| 111: Surface | 12: Metal layer |
| 121: First portion | 122: Second portion |
| 13: First region | 14: Second region |
| 141: Grooves | 20: Terminal |
| 21: First terminal | 211: Covered portion |
| 212: Exposed portion | 22: Second terminal |
| 221: Covered portion | 222: Exposed portion |
| 30: Semiconductor element | 31: First element |
| 311: First electrode | 312: Second electrode |
| 313: Third electrode | 32: Second element |
| 321: First electrode | 322: Second electrode |
| 39: First bonding layer | 40: Conductive member |
| 41: First member | 42: Second member |
| 43: Third member | 49: Second bonding layer |
| 50: Sealing resin | 51: Top surface |
| 52: Bottom surface | 53: First side surface |
| 54: Second side surface | 55: Opening |
| 56: Mounting hole | 80: Tie bar |
| 81: Bonding material | 821: First region |
| 822: Second region | 822A: Groove |
| 822B: Slit | 83: Sealing resin |
| 831: Resin burr | z: Thickness direction |
| x: First direction | y: Second direction |

1. A semiconductor device comprising:
a support member having an obverse surface facing in a thickness direction;
a semiconductor element mounted on the obverse surface; and
a bonding layer that bonds the obverse surface and the semiconductor element,
wherein the support member includes a base member, and a metal layer mounted on the base member and providing the obverse surface,
the support member includes a first region in contact with the bonding layer, and a second region adjacent to the first region as viewed in the thickness direction,
the bonding layer contains a metal composition in a solid phase, and
the second region is more repellent to a liquid phase of the metal composition than the first region.

2. The semiconductor device according to claim 1, wherein a surface roughness of the second region is greater than a surface roughness of the first region.

3. The semiconductor device according to claim 2, wherein the second region is formed with a plurality of grooves extending in a direction crossing the thickness direction and aligned in parallel to each other.

4. The semiconductor device according to claim 3, wherein the metal layer has a first portion included in the first region, and a second portion included in the second region.

5. The semiconductor device according to claim 4, wherein the base member is exposed from the second portion.

6. The semiconductor device according to claim 1, wherein the second region surrounds the first region as viewed in the thickness direction.

7. The semiconductor device according to claim 1, wherein the semiconductor element includes a first element and a second element that are spaced apart from each other, and
at least a portion of the second region is positioned between the first element and the second element, as viewed in the thickness direction.

8. The semiconductor device according to claim 1, wherein a composition of the base member includes copper.

9. The semiconductor device according to claim 1, wherein a composition of the metal layer includes silver.

10. The semiconductor device according to claim 1, wherein the metal composition contains tin.

11. The semiconductor device according to claim 1, further comprising
a terminal located away from the support member and electrically connected to the semiconductor element,
wherein at least a portion of the second region is positioned between the semiconductor element and the terminal, as viewed in the thickness direction.

12. The semiconductor device according to claim 11, wherein a composition of the terminal is the same as a composition of the base member.

13. The semiconductor device according to claim 11, further comprising a sealing resin covering the semiconductor element and a portion of each of the support member and the terminal,
wherein the sealing resin is in contact with the second region.

14. The semiconductor device according to claim 13, further comprising a conductive member bonded to the semiconductor element and the terminal,
wherein the conductive member is covered with the sealing resin.

15. The semiconductor device according to claim 13,
wherein the support member has a reverse surface facing away from the obverse surface in the thickness direction, and
the reverse surface is exposed from the sealing resin.

16. A method for manufacturing a semiconductor device, comprising the steps of:
forming a metal layer on a base member having an obverse surface facing in a thickness direction, such that the metal layer covers the obverse surface,
arranging a bonding material on a first region of the metal layer, the bonding material containing a metal composition;
arranging a semiconductor element on the bonding material; and
bonding the semiconductor element to the metal layer by melting and solidifying the bonding material,
wherein the method further comprises a step of irradiating a second region of the metal layer with a laser between the step of forming the metal layer and the step of arranging the semiconductor element, the second region being adjacent to the first region.

17. The method according to claim 16, wherein a plurality of grooves are formed in the second region in the step of irradiating the second region with a laser, the plurality of grooves extending in a direction crossing the thickness direction and being aligned in parallel to each other.

18. The method according to claim 16, wherein a plurality of slits are formed in the second region in the step of irradiating the second region with a laser, the plurality of slits extending in a direction crossing the thickness direction and being aligned in parallel to each other.
